(19) United States
(12) Patent Application Publication
(10) Pub. No.: US 2007/0004127 A1
(43) Pub. Date: Jan. 4, 2007

(54) Method of fabricating a transistor having the round corner recess channel structure

(76) Inventor: Jin Yul Lee, Seoul (KR)

Correspondence Address: LADAS & PARRY LLP, 224 SOUTH MICHIGAN AVENUE, SUITE 1600, CHICAGO, IL, 60604, US

(21) Appl. No.: 11/302,623

(22) Filed: Dec. 14, 2005

(30) Foreign Application Priority Data
Jun. 30, 2005 (KR) 10-2005-0058571

(51) Int. Cl. H01L 21/8242; H01L 21/302

(52) U.S. Cl. 438/243; 438/745; 257/E21.384

(57) ABSTRACT

In fabricating a transistor having the round corner recess channel structure, a buffer layer and a hard mask layer are formed in the active area of a semiconductor substrate. The buffer layer and the hard mask layer are etched so as to expose a predetermined channel region of the active area in the substrate. The predetermined channel region is wet etched to undercut the buffer layer below the hard mask layer. The exposed area of the substrate is etched by using the hard mask layer as an etching barrier so as to form a recess. The hard mask layer is removed. Light etch treatment is performed to round out the top corner of the recess. The buffer layer is then removed.

### BACKGROUND OF THE INVENTION

1. Field of the Invention

The present invention relates generally to a method of fabricating a semiconductor device, and more particularly to a method of fabricating a transistor with a recess channel structure, which can effectively improve a refresh characteristic.

2. Description of the Prior Art

Recently, as the design rule for developing semiconductor memory devices reduces the device sizes to fall below sub-100 nm, it has become very difficult to secure sufficient data retention time. When the minimum feature size of a device is reduced, the doping density in the substrate must then be increased. The increase in the doping density in the substrate will inevitably increase the electric field and the junction leakage. Therefore, in view of processing and device characteristics, a transistor having a conventional planar structure faces a limitation to realize a target threshold voltage Vt required by a certain semiconductor memory device.

Accordingly, a transistor having a recess channel structure, which extends the channel length, has been proposed as a method of decreasing the substrate doping density. Such a transistor would have the recess channel structure that can reduce the substrate doping density, thereby extending the data retention time. Further, such a transistor having the recess channel structure can lower the electric field, thereby making it possible to obtain an excellent refresh characteristic. In addition, as the channel length increases, it is possible to improve characteristics of the drain induced barrier lowering (DIBL) and the break down voltage (BVds), resulting in the improvement of the overall cell characteristics.

As described above, the recess channel structure can extend the data retention time by, for example, more than 200 ms, and further a cell transistor designed at the level of sub-90 nm must employ the recess channel structure.

Hereinafter, a conventional method of fabricating a transistor having a recess channel structure will be described in brief with reference to FIGS. 1A-1D.

Referring to FIG. 1A, a buffer oxide layer 3 and a polysilicon layer 4 for use as a hard mask are sequentially formed on a semiconductor substrate 1, which has device insulating layers 2 defining an active region therebetween. Next, a photo-resist pattern 5 is formed on the polysilicon layer 4 in order to expose the predetermined portions of the active region, in which the recess structure will be formed.

Referring to FIG. 1B, the polysilicon layer 4 is etched by using the photo-resist pattern 5 as an etching barrier, thereby exposing a portion of the buffer oxide layer 3 which corresponds to the predetermined recess region. Then, the photo-resist pattern 5 used as the etching barrier is removed.

Referring to FIG. 1C, the buffer oxide layer 3 and the substrate 1 are sequentially etched by using the polysilicon layer 4 as the etching barrier, so as to form recess 6 in the predetermined channel region.

Referring to FIG. 1D, the remaining polysilicon layer 5 and the buffer oxide layer 3 are removed. Next, a gate insulation layer 7, a gate conductive layer 8, and a gate hard mask layer 9 are sequentially formed, and then the gate hard mask layer 9, the gate conductive layer 8, and the gate insulation layer 7 are etched to form a recess gate 10 in each recess 6.

Finally, source/drain regions (not labeled in FIG. 1D) are formed in the substrate 1 at both sides of each recess gate 10 to accomplish the fabrication of the transistor having the conventional recess channel structure.

According to the conventional method of fabricating the transistor with the recess channel structure as described above, the top corner of the recess 6 (labeled “A” in FIG. 1C) is formed with a sharp corner, and this leads to degradation of the electric characteristics of the device. More specifically, a GOI CCST fail (relating to failure in the gate oxide integrity) occurs in the gates of the fabricated transistor. There is a problem in that a GOI CCST fail causes a yield of the transistor to be reduced in the fabrication of the transistors.

### SUMMARY OF THE INVENTION

Accordingly, the present invention has been developed in order to solve the above-mentioned and other problems occurring in the prior art, and an object of the present invention is to provide a method of fabricating a transistor with a recess channel structure, which can prevent occurrence of a GOI CCST fail which may be caused by the sharp corner of the recess in a semiconductor substrate.

Another object of the present invention is to provide a method of fabricating a transistor having a recess channel structure, which can prevent a GOI CCST fail so as to increase fabricating yield.

In order to accomplish these objects of the present invention, there is provided a method of fabricating a transistor having a recess channel structure, which comprises the steps of: forming a buffer layer and a hard mask layer on a semiconductor substrate which includes an isolation layer defining an active area; etching the buffer layer and the hard mask layer so as to expose a predetermined channel region of the active area in the substrate; wet-etching the resultant substrate in which the predetermined channel region is exposed so as to undercut the buffer layer below the hard mask layer; etching an exposed area of the substrate by using the hard mask layer as an etching barrier so as to form recess; removing the hard mask layer; performing a light etch treatment to the resultant substrate in which the hard mask layer is removed so as to form a top corner of the recess with a rounding corner; and removing the buffer layer.

Here, the buffer layer is formed with an oxide layer to have a thickness of 50˜150 Å. The hard mask layer is formed with a polysilicon layer to have a thickness of 800˜1200 Å.

In the step of undercutting the buffer layer below the hard mask layer, a first wet-etching process is performed for fifteen to twenty-five seconds by using Hydrogen Fluoride (HF) solution in which hydrogen and fluorine are mixed at a ratio of 50:1, and then a second wet-etching is carried out at a normal temperature by using SC-1 solution in which NH₄OH, H₂O₂, and H₂O are mixed at a ratio of 1:4:20.

The light etch treatment is carried out by using CH₄ and O₂ for fifteen to twenty seconds.

The method of fabricating the transistor having the recess channel structure according to the present invention further comprises the steps of: forming a gate in each recess; forming spacers at both sides of each gate; and forming source/drain regions at both sides of each gate including the spacers on the substrate, which follow the step of forming the top corner of the recess with the rounding corner.

Also, in order to accomplish these objects of the present invention, there is provided a method of fabricating a transistor having a recess channel structure, which comprises the steps of: forming a pad oxide layer and a pad nitride layer on the semiconductor substrate, in turn; forming a trench by etching the pad nitride layer, the pad oxide layer and the semiconductor substrate; forming a insulation layer on the pad nitride to fill the trench; polishing the insulation layer with a chemical mechanical polishing process until the pad nitride is expose; forming an isolation layer defining an active area by removing exposed the pad nitride layer; forming a hard mask layer on the isolation layer and remained the pad oxide layer; etching the hard mask layer and the pad oxide so as to expose a predetermined channel region of the active area in the substrate; wet-etching the resultant substrate in which the predetermined channel region is exposed so as to undercut the pad oxide layer below the hard mask layer; etching an exposed area of the substrate by using the hard mask layer as an etching barrier so as to form recess; removing the hard mask layer; performing a light etch treatment to the resultant substrate in which the hard mask layer is removed so as to form a top corner of the recess with a rounding corner; and removing the pad oxide layer.

Here, the hard mask layer is formed with a polysilicon layer to have a thickness of 800˜1200 Å.

In the step of undercutting the buffer layer below the hard mask layer, a first wet-etching process is performed for fifteen to twenty-five seconds by using Hydrogen Fluoride (HF) solution in which hydrogen and fluorine are mixed at a ratio of 50:1, and then a second wet-etching is carried out at a normal temperature by using SC-1 solution in which NH₄OH, H₂O₂, and H₂O are mixed at a ratio of 1:4:20.

The light etch treatment is carried out by using CH₄ and O₂ for fifteen to twenty seconds.

The method of fabricating the transistor having the recess channel structure according to the present invention further comprises the steps of: forming a gate in each recess; forming spacers at both sides of each gate; and forming source/drain regions at both sides of each gate including the spacers on the substrate, which follow the step of forming the top corner of the recess with the rounding corner.

### BRIEF DESCRIPTION OF THE DRAWINGS

The above and other objects, features, and advantages of the present invention will be more apparent from the following detailed description taken in conjunction with the accompanying drawings, in which:

FIGS. 1A through 1D are cross-sectional views for illustrating processing stages of a conventional method of fabricating a transistor having a recess channel structure;

FIGS. 2A through 2F are cross-sectional views for illustrating processing stages of a method of fabricating a transistor having a recess channel structure according to an embodiment of the present invention; and

FIG. 3 shows the top corner of a recess formed by an embodiment of the present invention and the top corner of a recess formed according to the conventional art for comparison; and

FIG. 4 is a graph for comparatively illustrating GOI CCST characteristics between the transistors having the recess channel structures according to an embodiment of the present invention and the transistors having the recess channel structures formed according to the conventional art.

### DETAILED DESCRIPTION OF THE PREFERRED EMBODIMENTS

Hereinafter, a preferred embodiment of the present invention will be described with reference to the accompanying drawings.

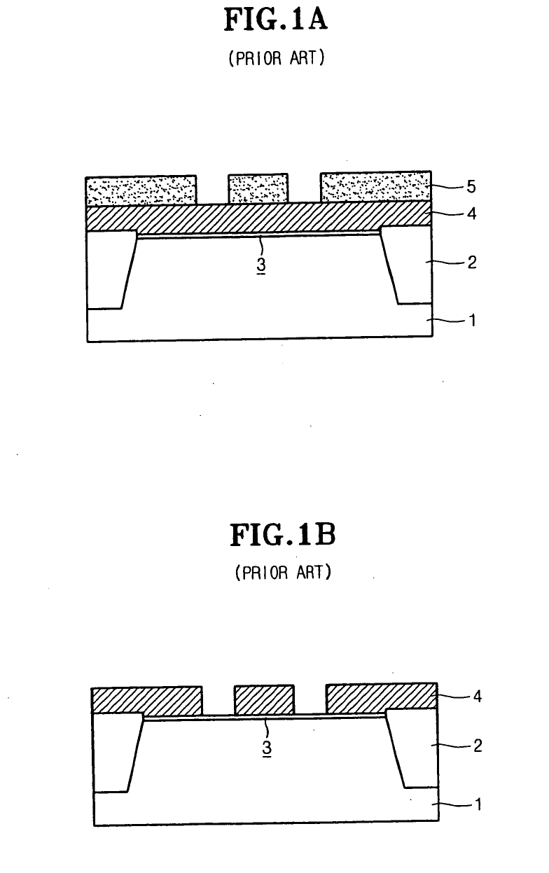

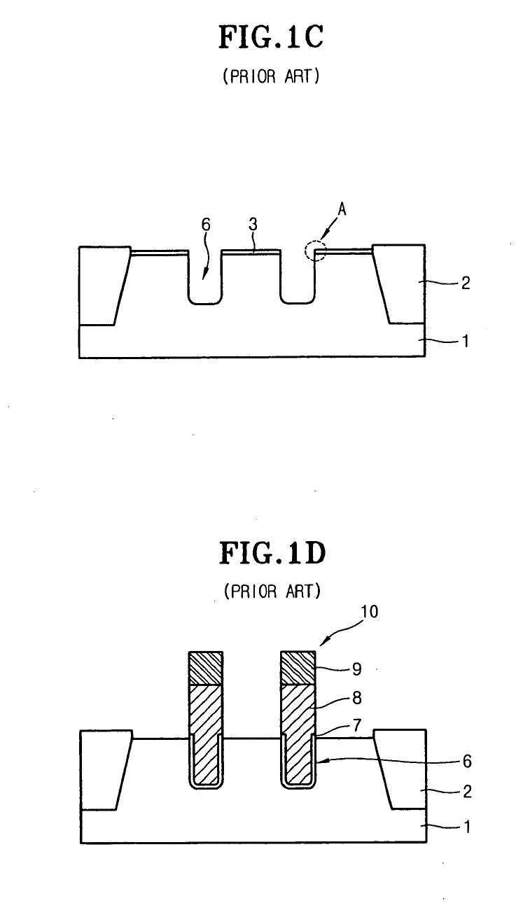

First, the technical principles of the present invention will be described. In the present invention, the sharp corner in a recess (such as FIGS. 1C, A) is eliminated. After etching a polysilicon layer used as a hard mask and a buffer oxide layer located below the polysilicon layer in a formation of a recess channel region, a retraction process is performed on the buffer oxide layer to remove some buffer oxide layer from a top corner of a recess in advance. Then, the semiconductor substrate is etched. In turn, a light etch treatment is carried out to the substrate to form a rounded corner at each top corner of the recess.

Therefore, formation of a sharp corner is fundamentally prevented by the remaining oxide layer during the etching of the substrate. Thus, the present invention not only solves a deterioration of the gate oxide integrity (GOI) characteristics but also achieves a profile of the rounded corner in the recess channel region, thereby improving the margin of threshold voltage and hence increasing the data retention time.

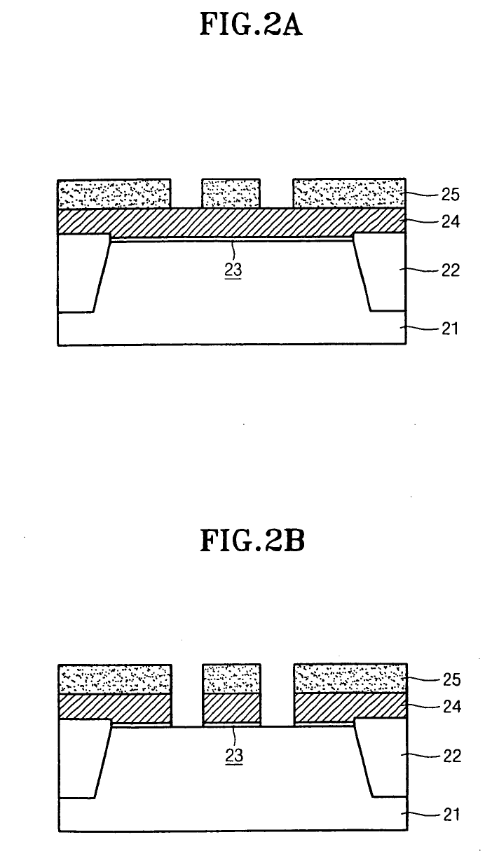

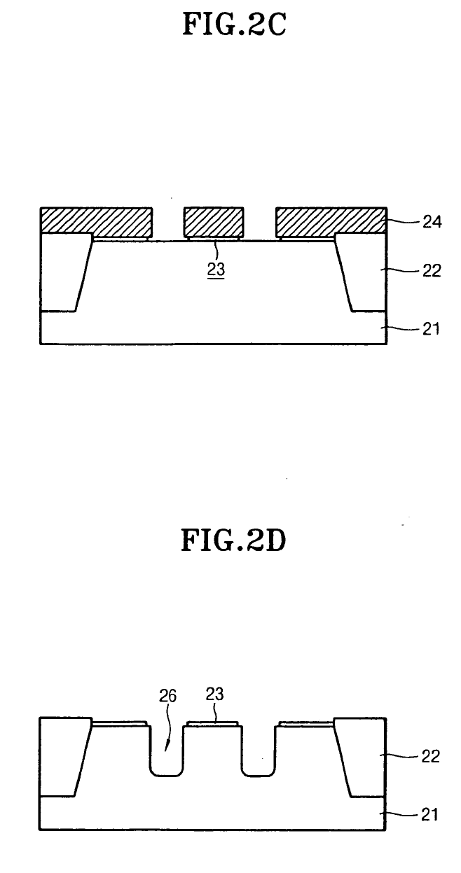

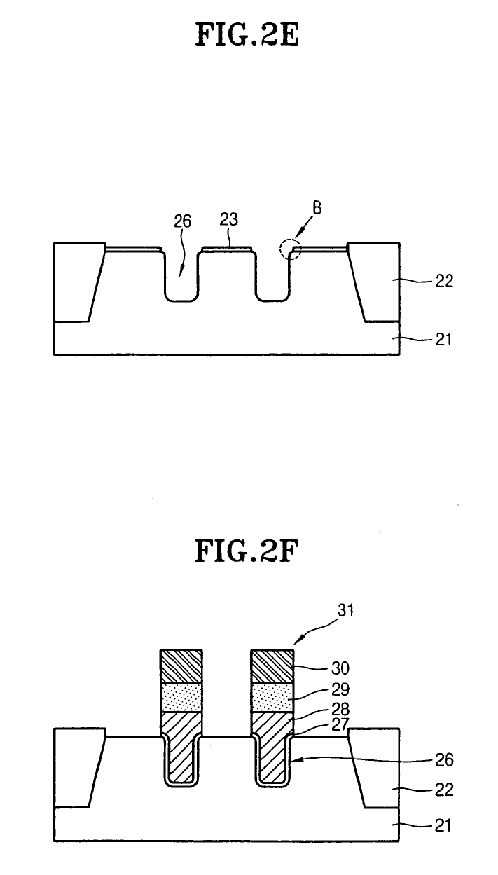

Hereinafter, a method of fabricating a transistor having a recess channel structure according to an embodiment of the present invention will be described in detail with reference to FIGS. 2A-2F.

Referring to FIG. 2A, a semiconductor substrate 21 is first formed with a number of isolation layers 22 to define the active area(s) in which the recess channel structure will be formed according to an embodiment of the present invention. A pad oxide layer (not shown) and a pad nitride layer (not shown) are sequentially formed first on the substrate 21, which are in turn subjected to the masking and etching processes to form trenches that are about 2000˜3000 Å deep from the surface of the semiconductor substrate 21. Next, an insulation layer is deposited on the substrate 21 to fill the trenches, and the excess insulation layer formed on the substrate 21 outside the trenches is polished by, for example, a chemical and mechanical polishing method. Then, the pad nitride layer (not shown) and the pad oxide layer (not shown) are removed. The insulation layer remaining in the trenches form the isolation layers 22 of trench type (as shown in FIG. 2A) defining the active area.

Then, a buffer layer 23 and a hard mask layer 24 are sequentially formed on the surface of the semiconductor substrate 21 including the isolation layer 22. Here, the buffer layer 23 is preferably an oxide layer with a thickness in the range of 50˜150 Å. Further, the hard mask layer 24 is preferably a polysilicon layer with a thickness in the range of 800˜1200 Å.

Next, a photo-resist pattern 25 is formed on the hard mask 24 to expose a predetermined channel region of the active area on the substrate 21.

Referring to FIG. 2B, the hard mask layer 24 and the buffer layer 23 are sequentially etched using the photo-resist pattern 25 as an etching barrier. This exposes the predetermined channel region of the substrate 21 that are to be recessed in further steps described below in detail. It is noted that the conventional art teaches etching only the hard mask layer 24 and not the buffer layer 23 (see FIG. 1B); however, both the hard mask layer 24 and the buffer layer 23 are etched together according to an embodiment of the present invention.

Referring to FIG. 2C, after removing the photoresist pattern 25, a wet-etching process is performed on the resultant substrate so that the end portions of the buffer layer 23 exposed by the etching are retracted—that is, during the wet etching process, the end portions of the buffer layer 23 is undercut below the hard mask layer 24 as shown in FIG. 2C.

The retraction of the buffer layer 23 is carried out by a first wet-etching process in a solution of hydrogen fluoride (HF) in which hydrogen and fluorine are mixed at a ratio of 50:1 for fifteen to twenty five seconds. This first wet-etching process is then followed by a second wet-etching process in a SC-1 solution (which is a type of cleaning solution) in which NH₄OH, H₂O₂, and H₂O are mixed at a ratio of 1:4:20. In this case, the second wet-etching process is carried out at a normal temperature.

Referring to FIG. 2D, the exposed region of the substrate 21 is etched at a predetermined depth by using the hard mask layer 24 as an etching barrier, so as to form a pluarality of recesses 26 defining the recess channel regions. Then, the hard mask layer 24 used as the etching barrier is removed.

Referring to FIG. 2E, the resultant substrate 21 having the buffer layer 23 and in which the recesses 26 are formed is undergoes another light etch treatment, by which the top corner of recess 26 (such as B shown in FIG. 2E) is rounded. Accordingly, as the present invention provides the rounding corner to the top corner B of recess in the substrate 21, the gate oxide integrity (GOI) characteristic of the transistor can be effectively prevented from deteriorating.

Referring to FIG. 2F, the buffer layer 23 is removed. Then, a gate oxide layer 27, a gate polysilicon layer 28, a gate tungsten silicide layer 29, and a hard mask nitride layer 30 are sequentially formed on the whole surface of the substrate 21 including the recesses 26, which now have the rounded top corners. Next, the hard mask nitride layer 30, the gate tungsten silicide layer 29, the gate polysilicon layer 28, and the gate oxide layer 27 are sequentially etched to form a recess gate 31 in each recess 26 as shown in FIG. 2F.

Thereafter, spacers (not shown) are formed at both sidewalls of each recess gate 31, and the source/drain regions (not labeled) are formed at both sides of each recess gate 31 including the spacers (not shown) on the surface of the substrate 21 so as to complete the the transistor having the recess channel structure according to an embodiment of the present invention.

In the method of fabricating the transistor with the recess channel structure according to an embodiment of the present invention as described above, the retraction of the buffer layer 23 is performed after etching the hard mask layer 24 and the buffer layer 23 together. Then, the light-etch treatment is carried out to the substrate, thereby forming the recesses respectively so as to have the rounded top corner in all recesses.

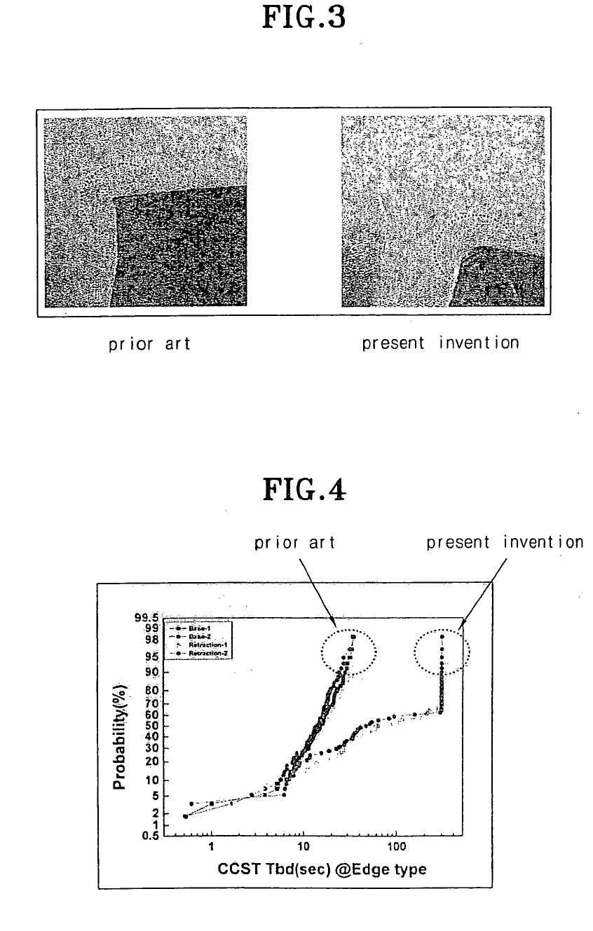

FIG. 3 is a view showing a comparative example of the top corner of the recess formed by an embodiment of the present invention and the top corner of the recess formed by the conventional art. As shown in FIG. 3, the conventional recess in the substrate has a sharp corner at the top corner of the recess. This causes the electric field to concentrate at the sharp corner of the recess in the substrate of the conventional device, and this will lead to the deterioration of the GOI CCST characteristic in the conventional transistor. According to an embodiment of the present invention, however, electric field is hardly concentrated at the rounded corner of the recess (shown with circle in FIG. 3), so that the deterioration of the GOI CCST characteristic does not occur in the transistor made in accordance with an embodiment of the present invention.

FIG. 4 is a graph for comparatively illustrating GOI CCST characteristics between the transistors having the recess channel structures according to an embodiment of the present invention and the transistors having the recess channel structures formed according to the conventional art.

FIG. 4 is a graph for illustrating the GOI CCST characteristics between the transistors having the recess channel structures according to an embodiment of the present invention and the transistors having the recess channel structures according to the conventional art. FIG. 4 shows that the present invention having the rounded top corner recesses provides much improved GOI CCST characteristic when compared to the conventional art having the sharp corner at the top corner of each recess.

Therefore, it is understood that the present invention can significantly improve the GOI characteristic by forming the rounded corner at the top corner of each recess during the formation of the recess channels.

Furthermore, the present invention can increase the margin of the threshold voltage by providing the rounded top corner for each recess in the substrate. As a result, the present invention can further improve the refresh characteristic.

In the above-mentioned embodiment of the present invention, an oxide layer is additionally formed to use as the buffer layer 23 when the recesses are formed in the semiconductor substrate. However, it is also possible that the pad oxide layer which would be formed in the formation of the isolation layer may be allowed to remain so that it can be used as the buffer layer 23, instead of removing the pad oxide layer and then depositing another oxide layer for use as the buffer layer 23.

This another embodiment of the present invention is described here. First, a pad oxide layer and a pad nitride layer are formed sequentially on a semiconductor substrate. A trench is then formed by sequentially etching the pad nitride layer, the pad oxide layer and the semiconductor substrate. Next, an insulation layer is formed on the pad nitride layer to fill the trenches, and then the insulation layer is polished away by a chemical mechanical polishing until the pad nitride is exposed. Then, the pad nitride layer is removed, thereby forming a trench type of the isolation layer defining an active area.

Next, a hard mask layer (such as 24 in FIG. 2C), which is made of a polysilicon layer, is formed to have 50˜150 Å on a whole surface of the semiconductor substrate (such as 21 in FIG. 2C) including the isolation layer (such as 22 in FIG. 2C). Herein, the remaining pad oxide is used as the buffer layer (such as 23 in FIG. 2C). Therefore, in another embodiment of the present invention, the buffer layer (such as 23 in FIG. 2C) is not separately formed with another oxide layer. The fabrication method is thus further simplified by this another embodiment of the present invention.

After this, the subsequent fabrication processes are same as the above-mentioned embodiment of the present invention described with reference to FIGS. 2A-2F, so that the transistor having the rounded corder recess channel structure is completed.

While a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A method of fabricating a transistor having a round corner recess channel structure in an active area of a semiconductor substrate defined by an isolation layer, the method comprising the steps of:
forming a buffer layer and a hard mask layer in the active area of the semiconductor substrate;
etching a portion of the buffer layer and the hard mask layer to expose a predetermined channel region in the active area;
wet-etching the exposed predetermined channel region to undercut an end portion of the buffer layer below the hard mask layer;
etching the exposed predetermined channel region of the substrate by using the hard mask layer as an etching barrier so as to form a recess in the substrate;
removing the hard mask layer;
performing a light etch treatment on the resultant substrate to round out a top corner of the recess; and
removing the buffer layer.

2. The method of claim 1, wherein the buffer layer is an oxide layer.

3. The method of claim 1, wherein the buffer layer has a thickness of 50˜150 Å.

4. The method of claim 1, wherein the hard mask layer is a polysilicon layer.

5. The method of claim 1, wherein the hard mask layer has a thickness of 800˜1200 Å.

6. The method of claim 1, wherein in the step of undercutting the buffer layer below the hard mask layer, a first wet-etching is performed for fifteen to twenty five seconds by using Hydrogen Fluoride (HF) solution in which hydrogen and fluorine are mixed at a ratio of 50:1 and then a second wet-etching is carried out by using SC-1 solution in which NH₄OH, H₂O₂, and H₂O are mixed at a ratio of 1:4:20.

7. The method of claim 6, wherein the second wet-etching is performed at a normal temperature.

8. The method of claim 1, wherein the light etch treatment is carried out by using CH₄ and O₂.

9. The method of claim 1, wherein the light etch treatment is carried out for fifteen to twenty seconds.

10. The method of claim 1 further comprising the steps of:
forming a gate in the recess having the rounded corner;
forming spacers at both sides of the gate; and
forming source/drain regions in the substrate at both sides of the gate.

11. A method of fabricating a transistor having a round corner recess channel structure in an active area of a semiconductor substrate defined by an isolation layer, the method comprising the steps of:
forming a pad oxide layer on the semiconductor substrate;
forming a pad nitride layer on the pad oxide layer;
forming a trench by etching a predetermined portion of the pad nitride layer, the pad oxide layer, and the semiconductor substrate;
forming a insulation layer on the pad nitride and in the trench;
polishing the insulation layer until the pad nitride layer is expose;
removing the pad nitride layer, wherein the insulation layer formed inside the trench is an isolation layer;
forming a hard mask layer on the isolation layer and on the pad oxide layer;
etching a predetermined portion of the hard mask layer and the pad oxide to expose a predetermined channel region of the active area in the substrate;
wet-etching the exposed predetermined channel region to undercut an end portion of the pad oxide layer below the hard mask layer;
etching the exposed predetermined channel region of the substrate by using the hard mask layer as an etching barrier so as to form a recess in the substrate;
removing the hard mask layer;
performing a light etch treatment on the resultant substrate to round out a top corner of the recess; and
removing the pad oxide layer.

12. The method of claim 11, wherein the hard mask layer is a polysilicon layer.

13. The method of claim 11, wherein the hard mask layer has a thickness of 800˜1200 Å.

14. The method of claim 11, wherein in the step of undercutting the buffer layer below the hard mask layer, a first wet-etching is performed for fifteen to twenty five seconds by using Hydrogen Fluoride (HF) solution in which hydrogen and fluorine are mixed at a ratio of 50:1 and then a second wet-etching is carried out by using SC-1 solution in which NH₄OH, H₂O₂, and H₂O are mixed at a ratio of 1:4:20.

15. The method of claim 14, wherein the second wet-etching is performed at a normal temperature.

16. The method of claim 1, wherein the light etch treatment is carried out by using CH₄ and O₂.

17. The method of claim 11, wherein the light etch treatment is carried out for fifteen to twenty seconds.

18. The method of claim 11, further comprising the steps of:
forming a gate in the recess;
forming spacers at both sides of the gate; and
forming source/drain regions at both sides of the gate including the spacers on the substrate.
